(19) United States
(12) Patent Application Publication
(10) Pub. No.: US 2026/0197012 A1
(43) Pub. Date: Jul. 9, 2026

(54) SUCCESSIVE APPROXIMATION ANALOG-TO-DIGITAL CONVERTER PERFORMING HYBRID REDUNDANCY OPERATION

(71) Applicant: SiliconGrid Co., Ltd, Giheung-gu (KR)

(72) Inventor: Sung Man PARK, Seongnam-si (KR)

(73) Assignee: SiliconGrid Co., Ltd, Giheung-gu (KR)

(21) Appl. No.: 19/367,446

(22) Filed: Oct. 23, 2025

(30) Foreign Application Priority Data
Jan. 3, 2025 (KR) 10-2025-0001058

(51) Int. Cl. H03M 1/46; H03M 1/66; H03M 1/68

(52) U.S. Cl. CPC H03M 1/462; H03M 1/662; H03M 1/68

(57) ABSTRACT

A successive approximation analog-to-digital converter includes a resistor digital-to-analog converter, including a plurality of series-connected resistors configured to provide a plurality of non-binary weighted divided voltages, a first capacitor digital-to-analog converter configured to: perform a non-binary Most Significant Bit (MSB) conversion process, using a first redundancy capacitor and a first non-binary weighted MSB capacitor array, for an analog input voltage, and perform a non-binary Least Significant Bit (LSB) conversion process, using a first LSB capacitor to which one of the non-binary weighted divided voltages is applied, thereby sequentially generating a first capacitor digital-to-analog converter output voltage, a second capacitor digital-to-analog converter configured to sequentially generate a second capacitor digital-to-analog converter output voltage, using a second redundancy capacitor, a second non-binary weighted MSB capacitor array, and a second LSB capacitor; and a comparator configured to compare the first capacitor digital-to-analog converter output voltage and the second capacitor digital-to-analog converter output voltage.

### CROSS-REFERENCE TO RELATED APPLICATION

The present application claims priority under 35 U.S.C. § 119(a) to Korean application number 10-2025-0001058, filed on Jan. 3, 2025, in the Korean Intellectual Property Office, which is incorporated herein by reference in its entirety.

### BACKGROUND

The present disclosure relates to an analog-to-digital converter.

During an operation of a successive approximation analog-to-digital converter (hereinafter referred to as SAR ADC), if an error occurs during an n-bit conversion due to various causes such as noise, process mismatch, or insufficient circuit operating speed, uncorrected data is output upon final conversion completion.

In particular, when using an internal LDO to generate an ADC voltage, an output of the LDO must have a sufficient driving capability. Otherwise, when the SAR ADC completes a sampling and starts a conversion from a most significant bit (hereinafter referred to as MSB), a capacitor to be driven is the largest, so it takes time for the LDO output to settle, causing the ADC voltage to fluctuate, and as the conversion approaches a least significant bit (hereinafter referred to as LSB), the LDO output becomes stable. That is, a large error may occur at the beginning of the conversion or during the conversion.

Conventional SAR ADCs implement the sampling capacitor array as a C-DAC (Capacitor Digital-to-Analog Converter) in a binary structure, or implement the upper bits using a binary capacitor array and the lower bits using a binary resistor array structure, i.e., an R-DAC (Resistor DAC). In order to add a redundancy bit for more improved characteristics, a redundancy capacitor is added to the binary C-DAC of the SAR ADC, or a redundancy step (bit) is added to transform it into a non-binary structure, thereby implementing redundancy operation.

### SUMMARY

The present disclosure is to improve a non-linear ADC error that occurs significantly at a specific location due to device mismatch and a comparator error effect of an SAR ADC.

According to one embodiment of the present disclosure, a successive approximation analog-to-digital converter is provided. The successive approximation analog-to-digital converter includes a resistor digital-to-analog converter, including a plurality of series-connected resistors connected between an upper reference voltage and a lower reference voltage, and configured to provide a plurality of non-binary weighted divided voltages; a first capacitor digital-to-analog converter, configured to: perform a non-binary Most Significant Bit (MSB) conversion process including a first redundancy bit, using a first redundancy capacitor and a first non-binary weighted MSB capacitor array, for an analog input voltage; and perform a non-binary Least Significant Bit (LSB) conversion process including a second redundancy bit, using a first LSB capacitor to which one of the plurality of non-binary weighted divided voltages is applied, thereby sequentially generating a first capacitor digital-to-analog converter output voltage; a second capacitor digital-to-analog converter, configured to sequentially generate a second capacitor digital-to-analog converter output voltage, using a second redundancy capacitor, a second non-binary weighted MSB capacitor array, and a second LSB capacitor; and a comparator, configured to compare the first capacitor digital-to-analog converter output voltage and the second capacitor digital-to-analog converter output voltage.

In the non-binary LSB conversion process, the non-binary weighted divided voltage applied to a bottom plate of the first LSB capacitor to determine an n^{th} bit varies depending on a value determined for an (n−1)^{th} bit.

The first capacitor digital-to-analog converter includes: the first redundancy capacitor, wherein a top plate of the first redundancy capacitor is connected to a first terminal of the comparator, and one selected from three non-binary weighted divided voltages among the plurality of non-binary weighted divided voltages is applied to a bottom plate thereof; the first non-binary weighted MSB capacitor array, including a plurality of capacitors, wherein top plates of the plurality of capacitors are connected to the first terminal of the comparator, and one of the analog input voltage, the upper reference voltage, or the lower reference voltage is applied to bottom plates thereof; and the first LSB capacitor, wherein a top plate of the first LSB capacitor is connected to the first terminal of the comparator, and a voltage selected from the analog input voltage, the plurality of non-binary weighted divided voltages, and the lower reference voltage is applied to the bottom plate thereof, and the second capacitor digital-to-analog converter includes: the second redundancy capacitor, wherein a top plate of the second redundancy capacitor is connected to a second terminal of the comparator, and a voltage selected from the plurality of non-binary weighted divided voltages, the upper reference voltage, and the lower reference voltage is applied to a bottom plate thereof; the second non-binary weighted MSB capacitor array, including a plurality of capacitors, wherein top plates of the plurality of capacitors are connected to the second terminal of the comparator, and a voltage selected from the upper reference voltage and the lower reference voltage is applied to bottom plates thereof; and the second LSB capacitor, wherein a top plate of the second LSB capacitor is connected to the second terminal of the comparator, and a voltage selected from the plurality of non-binary weighted divided voltages and the upper reference voltage is applied to a bottom plate thereof.

Based on the first capacitor digital-to-analog converter performing the non-binary LSB conversion process to generate the first capacitor digital-to-analog converter output voltage, the second capacitor digital-to-analog converter provides the second capacitor digital-to-analog converter output voltage corresponding to a first additional divided voltage which is higher than the upper reference voltage of the resistor digital-to-analog converter and corresponding to a second additional divided voltage which is lower than the lower reference voltage.

Based on the first additional divided voltage that is higher than the upper reference voltage by N_{RO} LSB being required at the bottom plate of the first LSB capacitor, a non-binary weighted divided voltage that is smaller by N_{RO} LSB than the non-binary weighted divided voltage applied to the bottom plate of the second LSB capacitor is applied, and based on the second additional divided voltage that is lower than the lower reference voltage by N_{RO} LSB being required at the bottom plate of the first LSB capacitor, a non-binary weighted divided voltage that is larger by N_{RO} LSB than the non-binary weighted divided voltage applied to the bottom plate of the second redundancy capacitor is applied.

Based on a number of digital codes being increased by the number of redundancy LSBs added by the first redundancy capacitor, the non-binary MSB conversion process and the non-binary LSB conversion process are performed by shifting a group of digital codes in a group, including those added by the redundancy LSBs, within a range of the added redundancy LSBs, and based on the non-binary MSB conversion process and the non-binary LSB conversion process being completed, the shifted redundancy LSBs are subtracted from the digital code composed of the converted MSB and LSB, and the first redundancy bit and the second redundancy bit are removed.

According to one embodiment of the present disclosure, a successive approximation analog-to-digital converter is provided. The successive approximation analog-to-digital converter includes a resistor digital-to-analog converter, including a plurality of series-connected resistors connected between an upper reference voltage and a lower reference voltage, and configured to provide a plurality of non-binary weighted divided voltages; a first capacitor digital-to-analog converter, configured to: perform a non-binary Most Significant Bit (MSB) conversion process including a first redundancy bit, using a first redundancy capacitor and a first non-binary weighted MSB capacitor array, for an analog input voltage; and perform a non-binary Least Significant Bit (LSB) conversion process including a second redundancy bit, using a first LSB capacitor to which one of the plurality of non-binary weighted divided voltages is applied, thereby sequentially generating a first capacitor digital-to-analog converter output voltage; a second capacitor digital-to-analog converter, configured to sequentially generate a second capacitor digital-to-analog converter output voltage, using a second redundancy capacitor, a second non-binary weighted MSB capacitor array, and a second LSB capacitor; a first capacitor multiplexer, configured to provide a voltage selected from the analog input voltage, the upper reference voltage, the lower reference voltage, and the plurality of non-binary weighted divided voltages to the first capacitor digital-to-analog converter; a second capacitor multiplexer, configured to provide a voltage selected from the upper reference voltage, the lower reference voltage, and the plurality of non-binary weighted divided voltages to the second capacitor digital-to-analog converter; a first resistor multiplexer, configured to select from the plurality of non-binary weighted divided voltages and provide to the first capacitor multiplexer; a second resistor multiplexer, configured to select from the plurality of non-binary weighted divided voltages and provide to the second capacitor multiplexer; a comparator, configured to compare the first capacitor digital-to-analog converter output voltage and the second capacitor digital-to-analog converter output voltage; and an SAR logic, configured to control the first capacitor multiplexer, the second capacitor multiplexer, the first resistor multiplexer, and the second resistor multiplexer according to an output of the comparator.

In the non-binary LSB conversion process, the first resistor multiplexer is configured to change the plurality of non-binary weighted divided voltages applied to a bottom plate of the first LSB capacitor to determine an n^{th} bit depending on a value determined for an (n−1)^{th} bit.

Based on the first capacitor digital-to-analog converter performing the non-binary LSB conversion process to generate the first capacitor digital-to-analog converter output voltage, the second resistor multiplexer is configured to change the plurality of non-binary weighted divided voltages provided to the second capacitor digital-to-analog converter so as to provide the second capacitor digital-to-analog converter output voltage corresponding to a first additional divided voltage which is higher than the upper reference voltage of the resistor digital-to-analog converter and corresponding to a second additional divided voltage which is lower than the lower reference voltage.

Based on the first additional divided voltage that is higher than the upper reference voltage by NRO LSB being required at the bottom plate of the first LSB capacitor, a non-binary weighted divided voltage that is smaller by NRO LSB than the non-binary weighted divided voltage applied to the bottom plate of the second LSB capacitor is applied, and based on the second additional divided voltage that being lower than the lower reference voltage by NRO LSB is required at the bottom plate of the first LSB capacitor, a non-binary weighted divided voltage that is larger by NRO LSB than the non-binary weighted divided voltage applied to the bottom plate of the second redundancy capacitor is applied.

According to one embodiment of the present disclosure, a successive approximation analog-to-digital converter is provided. The successive approximation analog-to-digital converter includes a first capacitor digital-to-analog converter, configured to perform a non-binary conversion process including a redundancy bit, using a first redundancy capacitor and a first non-binary weighted capacitor array, for an analog input voltage, thereby sequentially generating a first capacitor digital-to-analog converter output voltage; a second capacitor digital-to-analog converter, configured to sequentially generate a second capacitor digital-to-analog converter output voltage, using a second redundancy capacitor, and a second non-binary weighted capacitor array; and a comparator, configured to compare the first capacitor digital-to-analog converter output voltage and the second capacitor digital-to-analog converter output voltage, wherein, based on a number of digital codes being increased by a number of redundancy LSBs added by the first redundancy capacitor, the non-binary conversion process is performed by shifting a group of digital codes, including those added by the redundancy LSBs, within a range of the added redundancy LSBs, and based on the non-binary conversion process being completed, the shifted redundancy LSBs are subtracted from the digital code, and the redundancy bit is removed.

According to the present disclosure, the non-linear ADC error that occurs significantly at the specific location due to the device mismatch and the comparator error effect of the SAR ADC is greatly improved.

### BRIEF DESCRIPTION OF THE DRAWINGS

Hereinafter, the present disclosure will be described with reference to embodiments shown in the accompanying drawings. For ease of understanding, the same reference numerals have been assigned to the same components throughout the attached drawings. The configuration shown in the accompanying drawings is only an embodiment implemented by way of example to explain the present disclosure, and is not intended to limit the scope of the present disclosure thereto. In particular, in the accompanying drawings, some of the elements represented in the drawings are somewhat exaggerated to help understand the disclosure.

FIG. 1 schematically illustrates a successive approximation analog-to-digital converter performing a hybrid redundancy operation;

FIG. 2 illustrates a C-DAC and an R-DAC;

FIG. 3 illustrates DAC configuration of an SAR ADC that converts V_{IN} into a 10-bit digital code;

FIG. 4, FIG. 5 and FIG. 6 illustrate a non-binary MSB conversion process of a 10-bit SAR ADC in order;

FIG. 7 and FIG. 8 illustrate a non-binary LSB conversion process of the 10-bit SAR ADC;

FIG. 9 illustrates a binary search tree for determining a 6-bit digital code with a combination of a C-DAC and an R-DAC;

FIG. 10 illustrates a binary search tree for determining an 8-bit digital code with a combination of a C-DAC and an R-DAC; and

FIG. 11, FIG. 12 and FIG. 13 illustrate characteristics of the successive approximation analog-to-digital converter performing the hybrid redundancy operation.

### DETAILED DESCRIPTION

Embodiments which will be described below with reference to the accompanying drawings can be implemented singly or in combination with other embodiments. But this is not intended to limit the present disclosure to a certain embodiment, and it should be understood that all changes, modifications, equivalents or replacements within the spirits and scope of the present disclosure are included. Especially, any of functions, features, and/or embodiments can be implemented independently or jointly with other embodiments. Accordingly, it should be noted that the scope of the disclosure is not limited to the embodiments illustrated in the accompanying drawings.

Terms such as first, second, etc., may be used to refer to various elements, but, these elements should not be limited due to these terms. These terms will be used to distinguish one element from another element.

The terms used in the following description are intended to merely describe specific embodiments, but not intended to limit the disclosure. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present disclosure will be described in detail with reference to the related drawings. Throughout the accompanying drawings, the same or similar elements are cited using the same reference numerals.

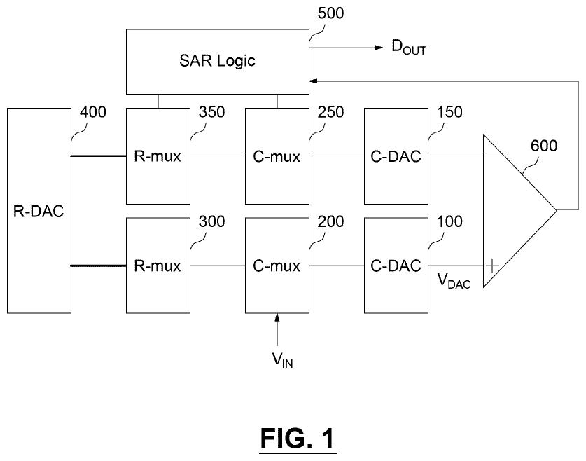

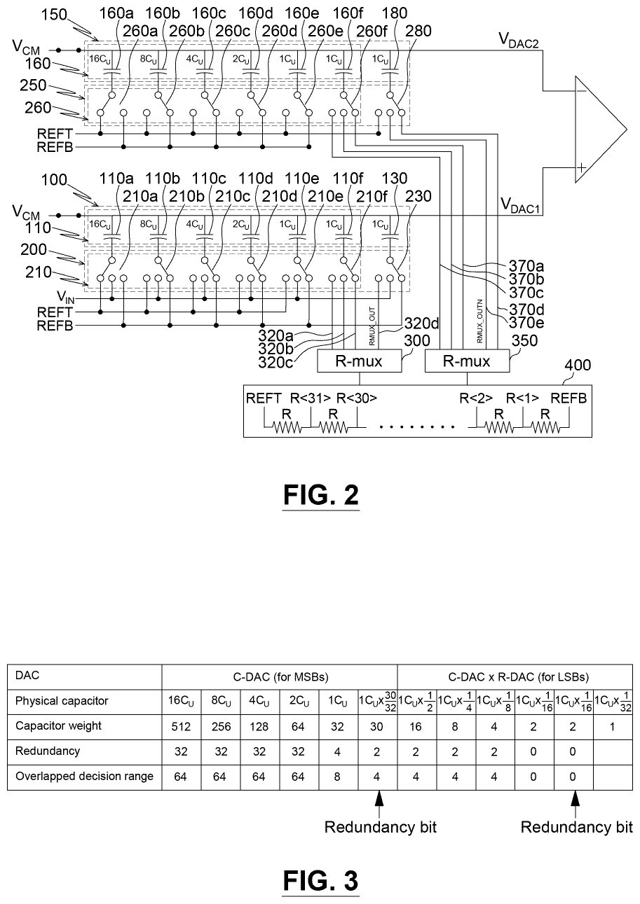

FIG. 1 schematically illustrates a successive approximation analog-to-digital converter performing a hybrid redundancy operation, FIG. 2 illustrates a C-DAC and an R-DAC, and FIG. 3 illustrates a DAC configuration of an SAR ADC that converts V_{IN} into a 10-bit digital code.

A successive approximation analog-to-digital converter (hereinafter referred to as SAR ADC) converts an analog input voltage V_{IN} into a corresponding n-bit (where n is a natural number) digital output signal D_{OUT}. The SAR ADC can be implemented with a single-ended structure in which the analog input voltage V_{IN} is input to a single DAC, and a differential structure in which differential analog input signals V_{INN} and V_{INP} are input to two DACs, respectively. Hereinafter, the description will focus on the single-ended structure.

One embodiment enables correction of errors in the final converted data by adding a redundancy capacitor or a redundancy conversion step to a C-DAC or an R-DAC so that an error can be corrected to some extent even if it occurs at the beginning or during an n-bit conversion. In addition, to improve a non-linear error that occurs significantly at a specific point due to effects such as device mismatch and a comparator error, a code of a redundancy bit operation is shifted to operate so that a linear characteristic of an ADC is improved.

Referring to FIG. 1, FIG. 2 and FIG. 3 together, SAR ADC may include capacitor digital-to-analog converters (hereinafter C-DAC) 100, 150, capacitor multiplexers (hereinafter C-MUX) 200, 250, a SAR logic 500, and a comparator 600. Additionally or alternatively, the SAR ADC may further include resistor multiplexers (hereinafter R-MUX) 300, 350 and a resistor digital-to-analog converter (hereinafter R-DAC) 400.

The first C-DAC 100 and the second C-DAC 150 includes a capacitor array connected to the C-MUX 200, 250. During sampling, the first C-DAC 100 is provided with the analog input voltage V_{IN} to sample and hold, and during conversion, the first C-DAC 100 sequentially generates a finite number of first digital-to-analog converter voltages V_{DAC1} generated by a combination of the sampled analog input voltage V_{IN} and a reference voltage REFT/REFB. Meanwhile, the second C-DAC 150 provides a coupling for limiting power/ground noise to the comparator 600, a code shift for utilizing a redundancy LSB added by a redundancy bit, and an additional divided voltage of ±N_{RO} LSB to cope with a range over of the R-DAC 400.

The first C-DAC 100 may include the first non-binary weighted MSB capacitor array 110 and the first LSB capacitor 130. Similarly, the second C-DAC 150 may include the second non-binary weighted MSB capacitor array 160 and the second LSB capacitor 180. The first non-binary weighted MSB capacitor array 110 and the second non-binary weighted MSB capacitor array 160 may be a non-binary weighted capacitor array. In the structure illustrated in FIG. 2, expressed using a unit capacitor (or capacitance) Cu, the first non-binary weighted MSB capacitor array 110 and the second non-binary weighted MSB capacitor array 160 may include 2⁴Cu, 2³Cu, 2²Cu, 2¹Cu, 2⁰Cu, and 2⁰Cu. The rightmost capacitor 2⁰Cu is a redundancy capacitor, and can be implemented as ‘a’ times the unit capacitor (a=natural number). Meanwhile, the LSB capacitors 130 and 180 may be 2° cu.

A top plate of the first C-DAC 100 is connected to a non-inverting terminal + of the comparator 600, so that V_{DAC1} is applied to the comparator 600. A top plate of the second C-DAC 150 is connected to an inverting terminal − of the comparator 600, so that the second digital-to-analog converter voltage V_{DAC2} to be compared with V_{DAC1} is applied to the comparator 600. When the redundancy operation is not performed, V_{DAC2} may be a common mode voltage V_{CM}. Meanwhile, when the redundancy operation is performed, a redundancy voltage V_{RED} for code shift is added to V_{DAC2}.

The first C-MUX 200 and the second C-MUX 250 include a plurality of switches 210, 230, 260, and 280 controlled by the SAR logic 500. The first C-MUX 200 and the second C-MUX 250 are connected to the bottom plates of the capacitors, to which one of the following voltages is applied: V_{IN}, REFT, REFB, or a divided voltage. Although not shown, V_{CM} may be applied to the bottom plates of the capacitors. V_{CM} may be, for example, a middle value between an upper reference voltage REFT and a lower reference voltage REFB.

The first C-MUX 200 may include first capacitor switches 210a to 210e for applying one of V_{IN}, REFT, and REFB to bottom plates of remaining first non-binary weighted MSB capacitors 110a to 110e excluding the first redundancy capacitor 110f, the first redundancy switch 210f for applying one of three divided voltages output from the first R-MUX 300 to a bottom plate of the first redundancy capacitor 110f, and the first LSB switch 230 for applying one of V_{IN}, REFB, and divided voltages (denoted as RMUX-OUT) for implementing resistor redundancy output from the first R-MUX 300 to the first LSB capacitor 130.

The second C-MUX 250 may include second capacitor switches 260a to 260e for applying one of REFT and REFB to bottom plates of remaining second non-binary weighted MSB capacitors 160a to 160e excluding the second redundancy capacitor 160f, the second redundancy switch 260f for applying one of three divided voltages output from the second R-MUX 350 to a bottom plate of the second redundancy capacitor 160f, and the second LSB switch 280 for applying one of REFT, REFB, and divided voltages (denoted as RMUX-OUTN) for implementing resistor redundancy output from the R-MUX 350 to the second LSB capacitor 180.

The first R-MUX 300 and the second R-MUX 350 provide divided voltages output from the R-DAC 400 to the first and second redundancy capacitors 110f, 160f and the first and second LSB capacitors 130, 180.

The first R-MUX 300 provides three divided voltages to the first redundancy switch 210f through three first connection lines 320a, 320b, 320c, and provides RMUX-OUT to the first LSB switch 230 through one first connection line 320d. The divided voltages RMUX-OUT for implementing resistor redundancy may be differently selected according to a value of a previous bit in a process of determining a digital code.

The second R-MUX 350 provides three divided voltages to the second redundancy switch 260f through three second connection lines 370a, 370b, and 370c, provides the divided voltages RMUX-OUTN for implementing resistor redundancy to the second LSB switch 280 through one 370d of two second connection lines 370d and 370e, and provides REFB through the other 370e. The three divided voltages provided to the second redundancy switch 260f through the three second connection lines 370a, 370b, and 370c can be selected according to a range of the code shift.

RMUX_OUTN is selected according to the value of the previous bit in the process of determining the digital code, and in particular, can be adjusted to supply an additional divided voltage when the range over occurs. Specifically, if an additional divided voltage higher than REFT by N_{RO} LSB is required, the second R-MUX 350 changes to a divided voltage smaller by N_{RO} LSB than the divided voltage being provided to the bottom plate of the second redundancy capacitor 160f. Meanwhile, if an additional divided voltage lower than REFB by N_{RO} LSB is required, the second R-MUX 350 changes to a divided voltage larger by N_{RO} LSB than the divided voltage being provided to the bottom plate of the second LSB capacitor 180.

The R-DAC 400 is a resistor array, and includes a plurality of series-connected resistors having substantially the same resistance in order to make a voltage applied to each of the plurality of resistors substantially the same, and provides 2^{k}−1 (where k is a natural number) non-binary weighted divided voltages. As shown in FIG. 2, the non-binary weighted divided voltages are R<1> to R<31>, and the resistor array is connected between REFT (=R<32>) and REFB (=R<0>). Meanwhile, for example, when N_{RO} is ±1, the R-DAC 400 can provide additional divided voltages R<−1> and R<33> that exceed (i.e., range over) the upper reference voltage REFT and the lower reference voltage REFB by the second LSB capacitor 180 of the second C-DAC 150.

The SAR logic 500 generates switching signals for controlling the first and second C-MUX 200, 250 and the first and second R-MUX 300, 350 to sample and convert V_{IN} therethrough, and to output an n-bit digital code as a conversion result.

The SAR logic 500 performs a non-binary MSB conversion process using the first C-DAC 100 to determine M+R₁ bits of MSB of a digital code, and performs a non-binary LSB conversion process by combining the first C-DAC 100 and the R-DAC 400 to determine L+R₂ bits of LSB of the digital code. n is M+L, R₁ (≥1) is a number of first redundancy bits by the first C-DAC 100, and R₂ (≥1) is a number of second redundancy bits by a combination of the first C-DAC 100 and the R-DAC 400. R₂ is the same as a number of redundancy steps of the non-binary LSB conversion process, and the number of redundancy steps and a position of the redundancy bit may be determined according to the redundancy LSB to be added in the non-binary LSB conversion process.

Referring to the table illustrated in FIG. 3, a DAC configuration of an SAR ADC that converts V_{IN} into a 10-bit digital code is illustrated. MSB capacitor weights of the first C-DAC 100 are 512, 256, 128, 64, 32, and 30, including a redundancy capacitor weight, 30, corresponding to the first redundancy bit, and LSB capacitor weights of the combination of the first C-DAC 100 and the R-DAC 400 are 16, 8, 4, 2, 2, and 1, including a weight, 2, corresponding to the second redundancy bit.

Implementing the C-DAC of a SAR ADC in a binary structure simplifies the architecture, but the LSB capacitor becomes extremely small, typically below 1 fF, making it difficult to implement using MIM (Metal-insulator-metal) capacitors. Consequently, it is implemented with a metal-oxide-metal (MOM) capacitor using a small parasitic capacitor of a metal layer. In this case, the LSB capacitor has a small sampling capacitance and is more affected by other parasitic capacitors.

Therefore, taking a 10-bit SAR ADC as an example, 5 bits of MSB are implemented with the C-DAC 100, 150 having a binary weighted capacitor array, and 5 bits of LSB are implemented with the R-DAC 400 having a binary resistor array, thereby implementing the SAR ADC with a conventional MIM capacitor (>10 fF). However, in this case, to implement a non-binary redundancy bit with the R-DAC 400, the divided voltage of the R-DAC 400 must be changed to implement a required redundancy step.

Meanwhile, the SAR logic 500 performs the code shift using the second C-DAC 150 to handle the range over of the R-DAC 400.

The comparator 600 compares V_{DAC1} of the first C-DAC 100 with V_{DAC2} of the second C-DAC 150 and outputs a comparison signal. The SAR logic 500 determines a bit corresponding to the comparison signal based on the comparison signal.

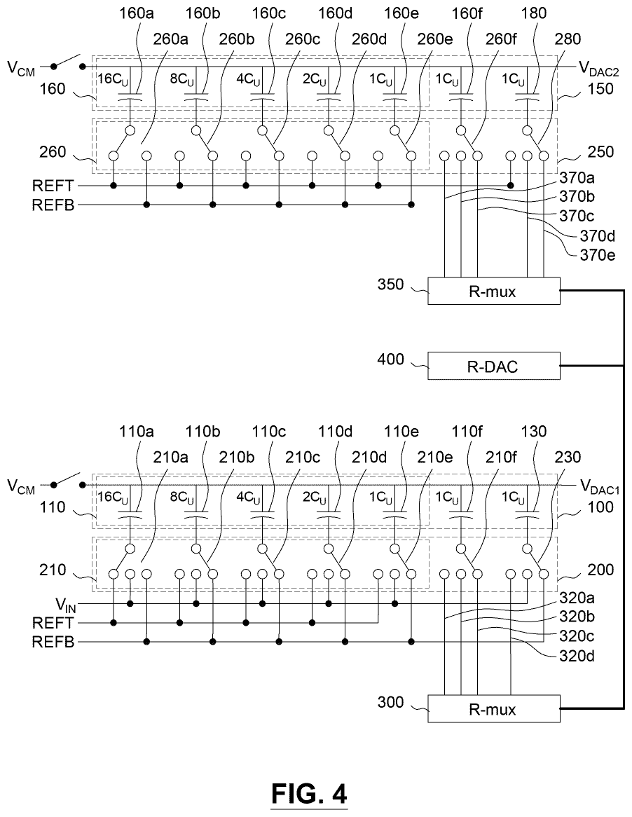

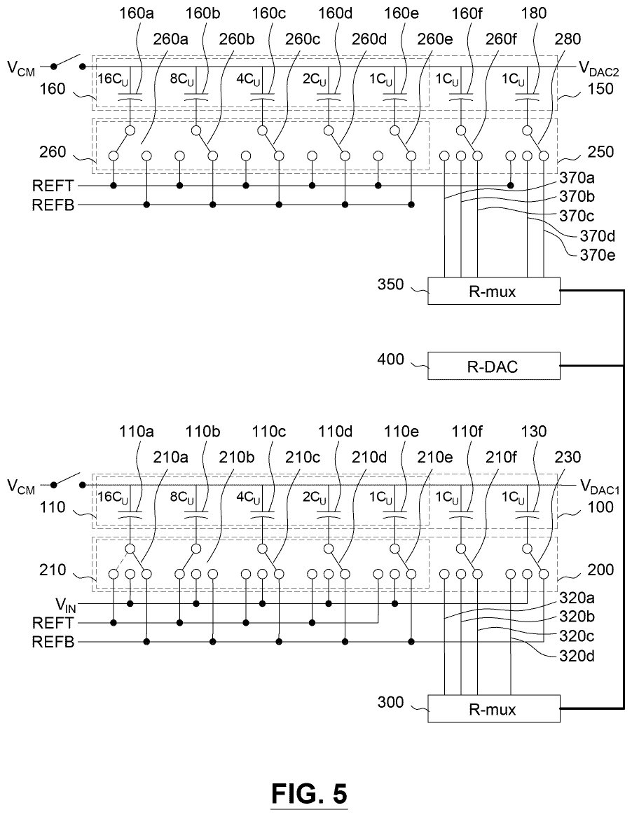

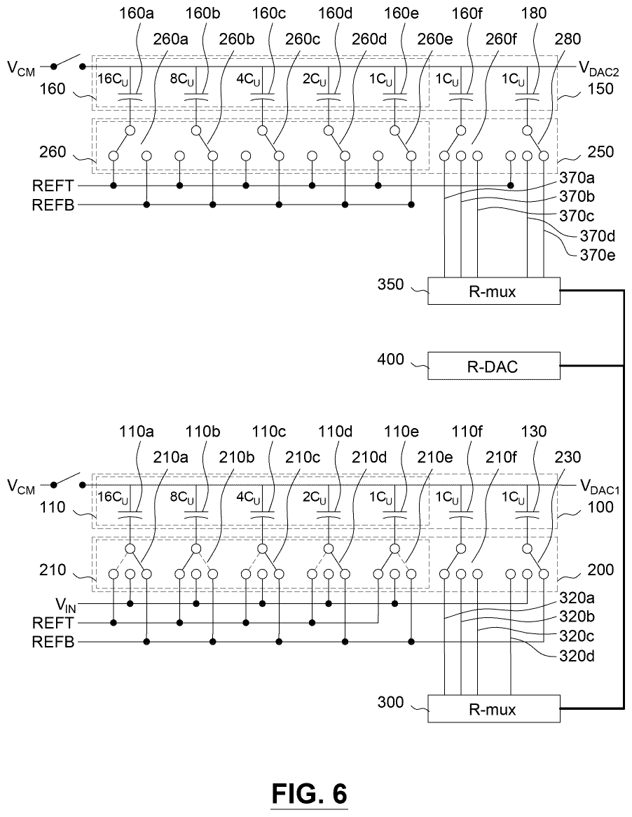

FIG. 4, FIG. 5 and FIG. 6 illustrate a non-binary MSB conversion process of a 10-bit SAR ADC in order. The non-binary MSB conversion process using the C-DAC 100, 150 is a process of determining a total of 6 bits including 1 redundancy bit.

Referring to FIGS. 4 to 6 together with FIG. 2, in which a sampling process is illustrated, V_{CM} is applied to the top plates of the capacitors included in the first C-DAC 100 and the second C-DAC 150 during the sampling. The C-MUX 200, 250 and the R-MUX 300, 350 operate under the control of the SAR logic 500.

The first C-MUX 200 switches to apply V_{IN} to the bottom plates of the first non-binary weighted MSB capacitor array 110 and the first LSB capacitor 130, and to connect to the first connection line 320b so that a divided voltage R<16>, which is a middle of divided voltages of the R-DAC 400, is applied to a bottom plate of the redundancy capacitor 110f.

The second C-MUX 250 switches to apply REFB to a bottom plate of the first non-binary weighted MSB capacitor switch 260a, which corresponds to the MSB, of the second non-binary weighted MSB capacitor array 160, and switches to apply REFT to bottom plates of remaining MSB capacitor switches 260b to 260e and the second LSB capacitor 180. Meanwhile, the second C-MUX 250 connects the second connection line 370b to the bottom plate of the second redundancy capacitor 160f to apply the divided voltage R<16>.

The first R-MUX 300 outputs REFT, R<16>, and R<16>, respectively, through the first connection lines 320a, 320b, 320c. The first connection line 320d will be used for the non-binary LSB conversion process.

The second R-MUX 350 may output a different combination of divided voltages through the second connection lines 370a, 370b, 370c according to the number of redundancy LSBs to be shifted. The code shift can be arbitrarily selected such as 0 LSB, 8 LSB, 16 LSB, 24 LSB, 32 LSB, etc., within 32 redundancy LSBs added by the redundancy capacitor. For example, when the code shift is 0 LSB, the second R-MUX 350 may output R<4>, R<28>, and R<16> through the second connection lines 370a, 370b, 370c. When the code shift is 16 LSB, the second R-MUX 350 may output R<4>, R<12>, and R<16> through the second connection lines 370a, 370b, 370c.

Meanwhile, the second R-MUX 350 outputs REFB through the second connection line 370e. The second connection line 370d will be used in the non-binary LSB conversion process.

Referring to FIG. 4, in order to determine the first bit of 6-bit MSB, the C-MUX 200, 250 and the R-MUX 300, 350 are operated by the control of the SAR logic 500. At the time of conversion, the top plates of the capacitors included in the first C-DAC 100 and the second C-DAC 150 are separated from V_{CM}.

In the first C-MUX 200, the first MSB switch 210a switches to apply REFT to the bottom plate of the first non-binary weighted MSB capacitor 110a, and remaining second to fifth MSB switches 210b to 210e and the first LSB switch 230 switch to apply REFB to bottom plates of second to fifth MSB capacitors 110b to 110e and the first LSB capacitor 130. The first redundancy switch 210f connects the first connection line 320c to the bottom plate of the first redundancy capacitor 110f to apply R<16>. As a result, V_{DAC1} for determining the first bit of the 6-bit MSB is applied to the non-inverting terminal of the comparator 600.

In the second C-MUX 250, the first MSB switch 260a switches to apply REFT to the bottom plate of the second non-binary weighted MSB capacitor 160a, and remaining second to fifth MSB switches 260b to 260e switch to apply REFB to bottom plates of the second to fifth MSB capacitors 160b to 160e. The second redundancy switch 260f connects the second connection line 370c to the bottom plate of the second redundancy capacitor 160f to apply R<16>. The second LSB switch 280 connects the second connection line 370e to the bottom plate of the second LSB capacitor 180 to apply REFB. The switching of the second C-MUX 250 is maintained until the sixth bit of the 6-bit MSB.

Referring to FIG. 5, the second bit of the 6-bit MSB is determined.

In the first C-MUX 200, the first MSB switch 210a connects one of REFT and REFB to the bottom plate of the first non-binary weighted MSB capacitor 110a according to the determined first bit of the 6-bit MSB. The second MSB switch 210b switches to apply REFT to the bottom plate of the second non-binary weighted MSB capacitor 110b. As a result, V_{DAC1} for determining the second bit of the 6-bit MSB is applied to the non-inverting terminal of the comparator 600.

Sequentially, the third MSB switch 210c, the fourth MSB switch 210d, and the fifth MSB switch 210e are connected to REFT to determine third to fifth bits of the 6-bit MSB.

Referring to FIG. 6, the sixth bit of the 6-bit MSB is determined.

In the first C-MUX 200, the first to fifth MSB switches 210a to 210e connect one of REFT and REFB to the bottom plates of the first to fifth MSB capacitors 110a to 110e, respectively, according to the determined first to fifth MSB bits. The first redundancy switch 210f connects the first connection line 320a to the bottom plate of the first redundancy capacitor 110f to apply REFT. As a result, V_{DAC1} for determining the sixth bit of the 6-bit MSB is applied to the non-inverting terminal of the comparator 600.

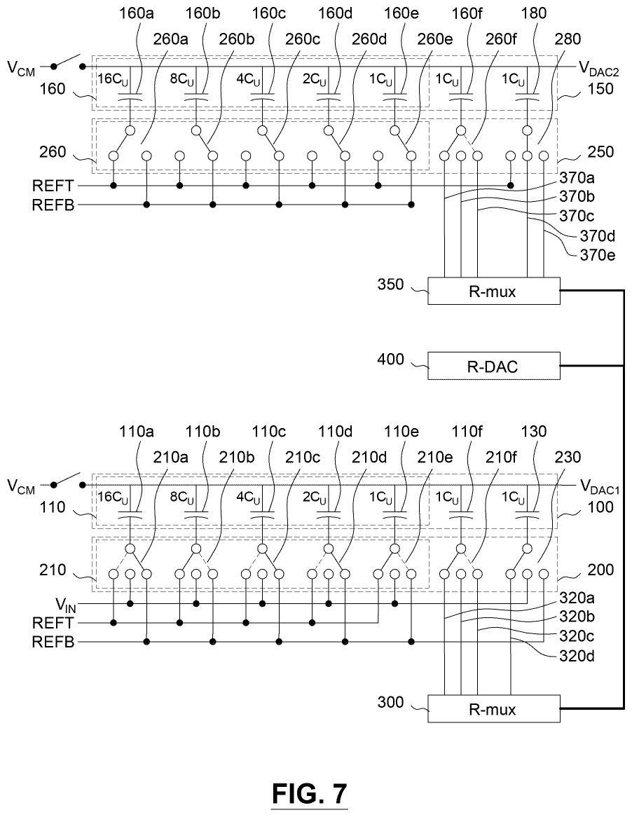

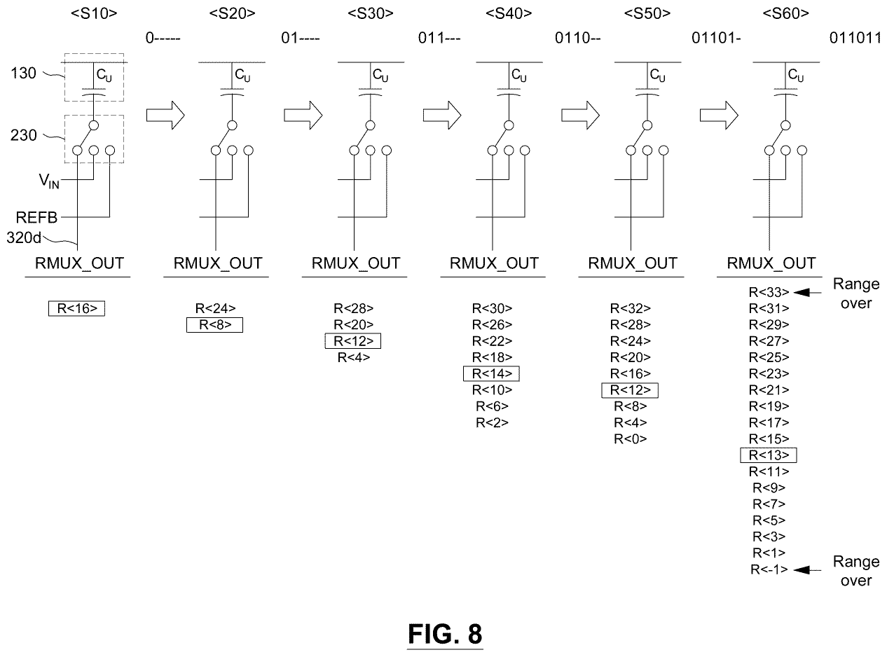

FIGS. 7 and 8 illustrate a non-binary LSB conversion process of a 10-bit SAR ADC.

Referring to FIG. 7, in the first C-MUX 200, when a 6-bit MSB including one redundancy bit is determined, the first to fifth MSB switches 210a to 210e connect one of REFT and REFB to the bottom plates of the first to fifth MSB capacitors 110a to 110e according to the determined first to fifth bits of the 6-bit MSB, and the first redundancy switch 210f connects one of the first connection line 320a for providing REFT and the first connection line 320c for providing R<16> to the first redundancy capacitor 110f according to the determined sixth bit of the 6-bit MSB. Meanwhile, the first LSB switch 230 connects the bottom plate of the first LSB capacitor 130 to the first connection line 320d to apply RMUX_OUT to the first LSB capacitor 130.

In the second C-MUX 250, the second redundancy switch 260f connects one of the second connection line 370a for providing R<4> and the first connection line 320c for providing R<16> to the second redundancy capacitor 160f according to the determined sixth bit of the 6-bit MSB. Meanwhile, the second LSB switch 280 connects the bottom plate of the second LSB capacitor 180 to the second connection line 370d to apply RMUX_OUTN to the second LSB capacitor 180.

Referring to FIG. 8, an LSB conversion using a combination of the C-DAC 100 and the R-DAC 400 is a process of determining a total of 6 bits including one redundancy bit. Switching of the first and second C-MUXs 200, 250 during the LSB conversion is maintained in the state illustrated in FIG. 7.

In S10, the first R-MUX 300 provides R<16> as RMUX_OUT to be applied to the bottom plate of the first LSB capacitor 130. As a result, V_{DAC1} for determining the first bit of the 6-bit LSB is applied to the non-inverting terminal of the comparator 600.

The second R-MUX 350 provides REFB as RMUX_OUTN to be applied to the bottom plate of the second LSB capacitor 180. REFB is provided until a situation occurs in which R<−1> needs to be provided, and when a situation occurs in which R<−1> needs to be provided, the second R-MUX 350 provides R<1> as RMUX_OUTN. Meanwhile, when a situation occurs in which R<33> needs to be provided, the second R-MUX 350 switches the second connection line 370a from R<4> to R<3>, and switches the second connection line 370c from R<16> to R<15>.

In S20, RMUX_OUT to be applied to the bottom plate of the first LSB capacitor 130 is determined according to the determined first bit of the 6-bit LSB. If the first LSB is 0, R<8> is provided as RMUX_OUT. As a result, V_{DAC1} for determining the second bit of the 6-bit LSB is applied to the non-inverting terminal of the comparator 600.

In S30, RMUX_OUT to be applied to the bottom plate of the first LSB capacitor 130 is determined according to the determined first and second bits of the 6-bit LSB. If the determined bits are 01, R<12> is provided as RMUX_OUT. As a result, V_{DAC1} for determining the third bit of the 6-bit LSB is applied to the non-inverting terminal of the comparator 600.

In S40, RMUX_OUT to be applied to the bottom plate of the first LSB capacitor 130 is determined according to the determined first to third bits. If the determined bits are 011, R<14> is provided as RMUX_OUT. As a result, V_{DAC1} for determining a fourth bit of the 6-bit LSB is applied to the non-inverting terminal of the comparator 600.

In S50, RMUX_OUT to be applied to the bottom plate of the first LSB capacitor 130 is determined according to the determined first to fourth bits. If the determined bits are 0110, R<12> is provided as RMUX_OUT. As a result, V_{DAC1} for determining a fifth bit of the 6-bit LSB is applied to the non-inverting terminal of the comparator 600.

In S60, RMUX_OUT to be applied to the bottom plate of the first LSB capacitor 130 is determined according to the determined first to fifth bits. If the determined LSB bits are 01101, R<13> is provided as RMUX_OUT. As a result, V_{DAC1} for determining a sixth LSB bit is applied to the non-inverting terminal of the comparator 600.

Through the processes described in FIGS. 3 to 8, 6-bit MSB including 1 redundancy bit and 6-bit LSB including 1 redundancy bit are determined. The SAR logic 500 subtracts a shifted redundancy LSB (0 LSB, 8 LSB, 16 LSB, 24 LSB, 32 LSB, etc.) from the determined digital code (6-bit MSB+6-bit LSB), and then removes two redundancy bits from the 6-bit MSB and 6-bit LSB to generate a 10-bit error-corrected digital code.

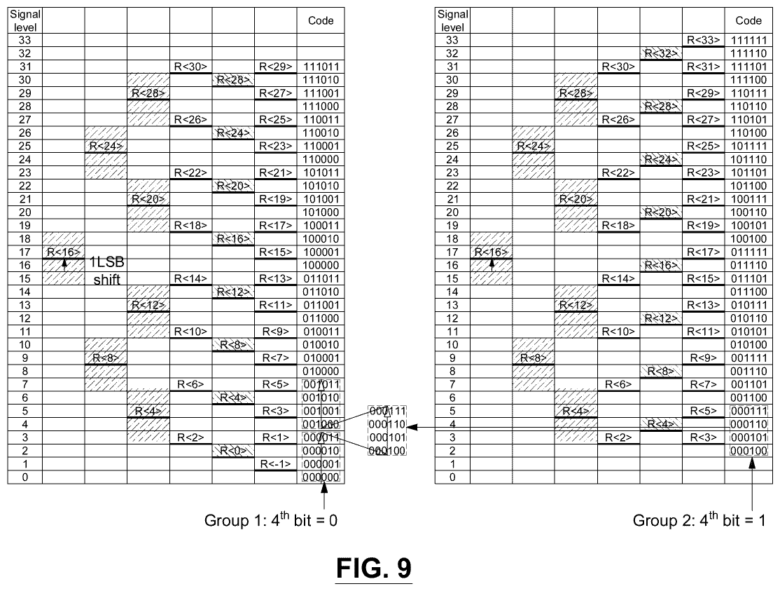

FIG. 9 illustrates a binary search tree for determining a 6-bit digital code with a combination of C-DAC and R-DAC.

An SAR ADC according to one embodiment of the present disclosure may combine C-DAC and R-DAC to determine L+R₂ bits of LSB. R₂ redundancy bits can be generated by adding a redundancy step R₂ times. The binary search tree illustrated in FIG. 9 is for converting an analog input voltage V_{IN} into a 6-bit digital code including 1 redundancy bit, and includes two groups according to the fourth bit, which is a bit immediately before the redundancy bit. The first group represents digital codes when the bit immediately preceding the redundancy bit is determined to be 0, and the second group represents digital codes when the bit immediately before the redundancy bit is determined to be 1.

TABLE 1

| Physical | C-DAC × R-DAC | | | | | |
|---|---|---|---|---|---|---|
| capacitor | 1Cu/2 | 1Cu/4 | 1Cu/8 | 1Cu/16 | 1Cu/16 | 1Cu/32 |
| Capacitor | 16 | 8 | 4 | 2 | 2 | 1 |
| Weight | | | | | | |
| Redundancy | 2 | 2 | 2 | 0 | 0 | |
| Overlapped | 4 | 4 | 4 | 0 | 0 | |
| Decision range | | | | | | |

By converting 32 signal levels from 0 to 31 into 6-bit LSB and adding a redundancy bit, it becomes possible to convert 34 signal levels from 0 to 33 into 6-bit LSB. In particular, if the binary search tree is separated into two groups according to the bit immediately preceding the redundancy bit, 64 digital codes that can be determined by 6 bits can be separated into two group having 32 digital codes each. As a result, an overlapping problem of digital codes that occurs in a non-separated binary search tree is resolved, and one signal level can be found with two codes by adding the redundancy bit, so that a correct digital code can be finally found even if there is an error in the first conversion or a next conversion.

In the first group, after proceeding with a redundancy step with R<0>, if the redundancy bit is determined to be 0, R<−1> is required in the sixth step. R<−1> is smaller than REFB, so it is out of a divided voltage range that the R-DAC can provide. In this case, the second R-MUX 350 changes REFB, which was provided as RMUX_OUTN to the bottom plate of the second LSB capacitor 180, to R<1>. Due to this, an additional divided voltage corresponding to R<−1> can be applied to the bottom plate of the first LSB capacitor 130.

Meanwhile, in the second group, after proceeding with a redundancy step with R<32>, if the redundancy bit is determined to be 1, R<33> is required in the sixth step. Like R<−1>, R<33> is larger than REFT, so it is out of the divided voltage range that the R-DAC can provide. In this case, the second R-MUX 350 switches the second connection line 370a from R<4> to R<3>, and switches the second connection line 370c from R<16> to R<15>. Due to this, an additional divided voltage corresponding to R<33> can be applied to the bottom plate of the first LSB capacitor 130.

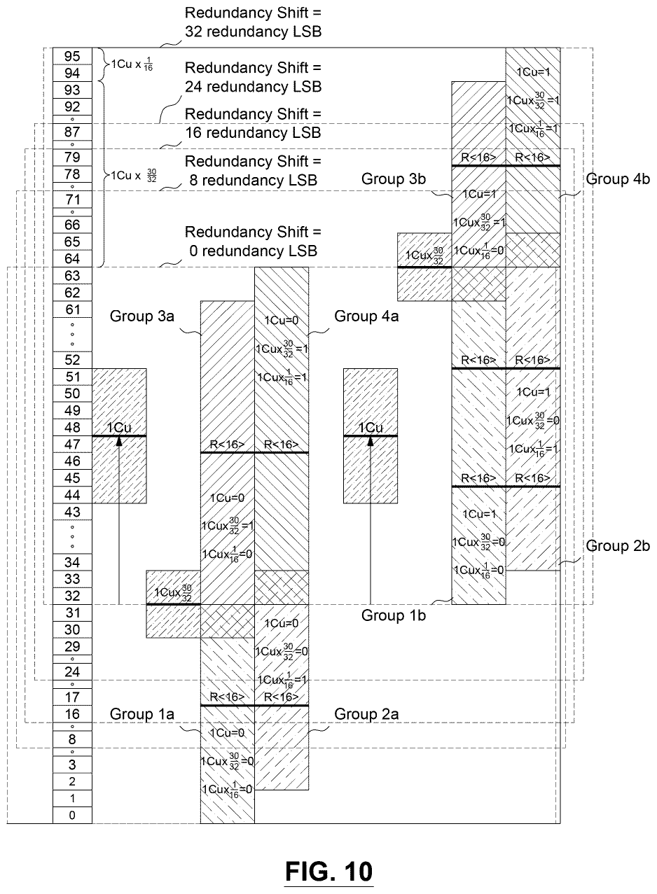

FIG. 10 illustrates a binary search tree for determining an 8-bit digital code with a combination of C-DAC and R-DAC.

A binary search tree for determining an n-bit digital code may be divided into a plurality of groups. If a redundancy bit is an m^{th} bit, a group may be divided by a value of an (m−1)^{th} bit which is 1 bit immediately preceding the redundancy bit (hereinafter referred to as a preceding bit). For example, in an 8-bit digital code, if the second bit and a seventh bit from the left are redundancy bits, a group may be divided into a combination of the first bit and a sixth bit from the left. By dividing the binary search tree into a plurality of groups, a signal level that can be converted also increases.

The redundancy capacitor generates a surplus digital code. As in the case illustrated in FIG. 10, when 64 signal levels from 0 to 63 are converted into an 8-bit digital code including two redundancy bits, a surplus digital code is generated due to the redundancy bits. 30 redundancy LSBs are generated by the second bit and 2 redundancy LSBs are generated by the seventh bit, so that a total of N_{R} (=32) redundancy LSBs (in other words, signal levels or digital codes) are added. Therefore, a signal level that the SAR ADC can convert is increased from 0-63 to 0-95.

When a code shift is executed, increased signal levels can also be used. When 32 signal levels are added, if a conversion starts from signal level 48 using the illustrated group (i.e., code shift=0 redundancy LSB), signal level 64 to signal level 95 are not used. On the other hand, in the same case, if starting from signal level 64 by shifting by 16 redundancy LSBs, signal level 16 to signal level 79 can be used.

The digital code converted by executing the code shift may remove the redundancy bit(s) after subtracting a code by a shifted redundancy LSB.

Referring to FIG. 10, the SAR ADC according to one embodiment of the present disclosure may determine 2 bits of MSB using C-DAC, and may determine 6 bits of LSB by combining C-DAC and R-DAC. A 1-bit redundancy bit may be generated using a redundancy capacitor of C-DAC, and a 1-bit redundancy bit may be generated by adding a redundancy step to a conversion process using the combination of C-DAC and R-DAC.

In the binary search tree for converting an analog input voltage V_{IN} into an 8-bit digital code including 2 redundancy bits, the second bit from the left is the first redundancy bit generated using the redundancy capacitor of C-DAC, and the seventh bit is the second redundancy bit generated by the redundancy step using the combination of C-DAC and R-DAC.

Groups 1a and 1b are digital codes in which the first bit, which is a bit immediately preceding the first redundancy bit, and the sixth bit, which is a bit immediately preceding the second redundancy bit, are both 0, groups 2a and 2b are digital codes in which the first bit and the sixth bit are 0 and 1, groups 3a and 3b are digital codes in which the first bit and the sixth bit are 1 and 0, and groups 4a and 4b are digital codes in which the first bit and the sixth bit are both 1.

TABLE 2

| Physical | C-DAC | | C-DAC × R-DAC | | | | | |
|---|---|---|---|---|---|---|---|---|
| capacitor | 1Cu | 30Cu/32 | 1Cu/2 | 1Cu/4 | 1Cu/8 | 1Cu/16 | 1Cu/16 | 1Cu/32 |
| Capacitor Weight | 32 | 30 | 16 | 8 | 4 | 2 | 2 | 1 |
| Redundancy | 4 | 2 | 2 | 2 | 2 | 0 | 0 | |
| Overlapped | 8 | 4 | 4 | 4 | 4 | 0 | 0 | |
| Decision range | | | | | | | | |

Except for 2 MSB bits, digital codes of groups 1a, 1b, 3a, and 3b in which the sixth bit is 0 are the same as group 1 of FIG. 9, and digital codes of groups 2a, 2b, 4a, and 4b in which the sixth bit is 1 are the same as group 2 of FIG. 9.

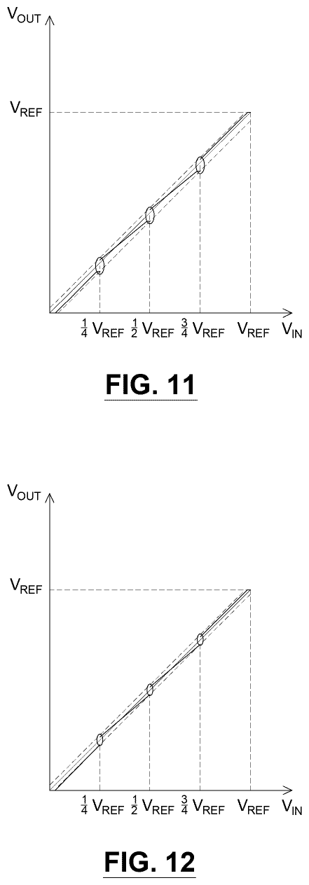

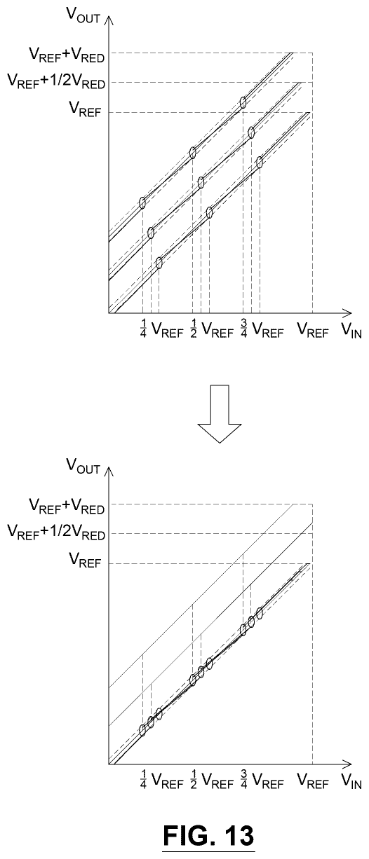

FIG. 11, FIG. 12 and FIG. 13 illustrate characteristics of the successive approximation analog-to-digital converter performing the hybrid redundancy operation.

FIG. 11 shows a characteristic of a relationship between a DAC input voltage (or, an input analog voltage) V_{IN} and a DAC output voltage V_{OUT} of a conventional SAR ADC to which no redundancy bit is added. In general, the ADC characteristic shows the largest non-linear error characteristic at ¼, ½, and ¾ points of a reference voltage V_{REF} when there is no redundancy bit, a mismatch of a capacitor is large, or a mismatch of a comparator is large and a speed is slow.

FIG. 12 shows a characteristic of a conventional SAR ADC to which a redundancy bit is added. If a redundancy bit is added to improve a non-linear characteristic, a more linear improved characteristic can be made, but since a mismatch of a capacitor is fundamentally unavoidable, it still has a non-linear characteristic to some extent.

FIG. 13 shows a characteristic of a non-binary structure in which a redundancy bit is added, operates with incremented digital codes up to N_{R} redundancy LSBs corresponding to V_{RED}, and subtracts the incremented digital codes in a final step to obtain the correct digital code. At this time, ½V_{REF}, ¼V_{REF}, and ¾V_{REF} points showing a bad non-linear error are also shifted according to the incremented N_{R} redundancy LSBs.

Therefore, within the range of the added V_{RED} or N_{R} redundancy LSBs, the digital code can be incremented by any number of redundancy LSBs, and the incremented digital code can be subtracted in the final step. Therefore, if the code shift is changed every time the same V_{IN} is converted a plurality of times (i.e., oversampling) and this is averaged, a result with a smaller non-linear error (INL, DNL) can be obtained than averaging after conversion in the fixed state. Thus, it is possible to further increase accuracy not only around ½V_{REF}, ¼V_{REF}, and ¾V_{REF}, which show the worst non-linear error characteristics, but also in an entire range.

The above description of the disclosure is exemplary, and those skilled in the art can understand that the disclosure can be modified in other forms without changing the technical concept or the essential feature of the disclosure. Therefore, it should be understood that the above-mentioned embodiments are exemplary in all respects, but are not definitive. In particular, the features of the present disclosure described with reference to the drawings are not limited to the structure shown in a specific drawing, and may be implemented independently or in combination with other features.

The scope of the disclosure is defined by the appended claims, not by the above detailed description, and it should be construed that all changes or modifications derived from the meanings and scope of the claims and equivalent concepts thereof are included in the scope of the disclosure.

What is claimed is:

1. A successive approximation analog-to-digital converter, comprising:
a resistor digital-to-analog converter comprising a plurality of series-connected resistors connected between an upper reference voltage and a lower reference voltage, and configured to provide a plurality of non-binary weighted divided voltages;
a first capacitor digital-to-analog converter configured to:
perform a non-binary Most Significant Bit (MSB) conversion process including a first redundancy bit, using a first redundancy capacitor and a first non-binary weighted MSB capacitor array, for an analog input voltage; and
perform a non-binary Least Significant Bit (LSB) conversion process including a second redundancy bit, using a first LSB capacitor to which one of the plurality of non-binary weighted divided voltages is applied, thereby sequentially generating a first capacitor digital-to-analog converter output voltage;
a second capacitor digital-to-analog converter configured to sequentially generate a second capacitor digital-to-analog converter output voltage, using a second redundancy capacitor, a second non-binary weighted MSB capacitor array, and a second LSB capacitor; and
a comparator configured to compare the first capacitor digital-to-analog converter output voltage and the second capacitor digital-to-analog converter output voltage.

2. The successive approximation analog-to-digital converter of claim 1, wherein the first LSB capacitor comprises a bottom plate, and wherein in the non-binary LSB conversion process, the plurality of non-binary weighted divided voltages is applied to the bottom plate of the first LSB capacitor to determine an n^{th} bit varies depending on a value determined for an (n−1)^{th} bit.

3. The successive approximation analog-to-digital converter of claim 1, wherein the comparator comprises a first terminal and a second terminal,
wherein the first capacitor digital-to-analog converter comprises:
the first redundancy capacitor having:
a top plate thereof to be connected to the first terminal of the comparator; and
a bottom plate thereof to which one selected from three non-binary weighted divided voltages among the plurality of non-binary weighted divided voltages is applied;
the first non-binary weighted MSB capacitor array, comprising a plurality of capacitors having:
top plates thereof to be connected to the first terminal of the comparator; and
bottom plates thereof to which one of the analog input voltage, the upper reference voltage, and the lower reference voltage is applied; and
the first LSB capacitor having:
a top plate of the first LSB capacitor to be connected to the first terminal of the comparator; and
a bottom plate to which a voltage selected from the analog input voltage, the plurality of non-binary weighted divided voltages, and the lower reference voltage is applied,
wherein the second capacitor digital-to-analog converter comprises:
the second redundancy capacitor having:
a top plate thereof to be connected to the second terminal of the comparator; and
a bottom plate thereof to which a voltage selected from the plurality of non-binary weighted divided voltages, the upper reference voltage, and the lower reference voltage is applied;
the second non-binary weighted MSB capacitor array, comprising a plurality of capacitors comprising:
top plates of the plurality of capacitors to be connected to the second terminal of the comparator; and
bottom plates thereof to which a voltage selected from the upper reference voltage and the lower reference voltage is applied; and
the second LSB capacitor comprising:
a top plate of the second LSB capacitor to be connected to the second terminal of the comparator; and
a bottom plate to which a voltage selected from the plurality of non-binary weighted divided voltages and the upper reference voltage.

4. The successive approximation analog-to-digital converter of claim 3, wherein, based on the first capacitor digital-to-analog converter performing the non-binary LSB conversion process to generate the first capacitor digital-to-analog converter output voltage, the second capacitor digital-to-analog converter provides the second capacitor digital-to-analog converter output voltage corresponding to a first additional divided voltage which is higher than the upper reference voltage of the resistor digital-to-analog converter and corresponding to a second additional divided voltage which is lower than the lower reference voltage.

5. The successive approximation analog-to-digital converter of claim 4, wherein, based on the first additional divided voltage that is higher than the upper reference voltage by N_{RO} LSB being required at the bottom plate of the first LSB capacitor, a non-binary weighted divided voltage that is smaller by N_{RO} LSB than the non-binary weighted divided voltage applied to the bottom plate of the second LSB capacitor is applied, and based on the second additional divided voltage that being lower than the lower reference voltage by N_{RO} LSB is required at the bottom plate of the first LSB capacitor, a non-binary weighted divided voltage that is larger by N_{RO} LSB than the non-binary weighted divided voltage applied to the bottom plate of the second redundancy capacitor is applied.

6. The successive approximation analog-to-digital converter of claim 1, wherein based on a number of digital codes being increased by a number of redundancy LSBs added by the first redundancy capacitor, the non-binary MSB conversion process and the non-binary LSB conversion process are performed by shifting a group of digital codes in a group, including those added by the redundancy LSBs, within a range of the added redundancy LSBs,
wherein, based on the non-binary MSB conversion process and the non-binary LSB conversion process being completed, the shifted redundancy LSBs are subtracted from the digital code composed of the converted MSB and LSB, and the first redundancy bit and the second redundancy bit are removed.

7. A successive approximation analog-to-digital converter, comprising:
a resistor digital-to-analog converter comprising a plurality of series-connected resistors connected between an upper reference voltage and a lower reference voltage, and configured to provide a plurality of non-binary weighted divided voltages;
a first capacitor digital-to-analog converter, configured to:
perform a non-binary Most Significant Bit (MSB) conversion process including a first redundancy bit, using a first redundancy capacitor and a first non-binary weighted MSB capacitor array, for an analog input voltage; and
perform a non-binary Least Significant Bit (LSB) conversion process including a second redundancy bit, using a first LSB capacitor to which one of the plurality of non-binary weighted divided voltages is applied, thereby sequentially generating a first capacitor digital-to-analog converter output voltage;
a second capacitor digital-to-analog converter configured to sequentially generate a second capacitor digital-to-analog converter output voltage, using a second redundancy capacitor, a second non-binary weighted MSB capacitor array, and a second LSB capacitor;
a first capacitor multiplexer configured to provide a voltage selected from the analog input voltage, the upper reference voltage, the lower reference voltage, and the plurality of non-binary weighted divided voltages to the first capacitor digital-to-analog converter;
a second capacitor multiplexer configured to provide a voltage selected from the upper reference voltage, the lower reference voltage, and the plurality of non-binary weighted divided voltages to the second capacitor digital-to-analog converter;
a first resistor multiplexer configured to select from the plurality of non-binary weighted divided voltages and provide to the first capacitor multiplexer;
a second resistor multiplexer configured to select from the plurality of non-binary weighted divided voltages and provide to the second capacitor multiplexer;
a comparator configured to compare the first capacitor digital-to-analog converter output voltage and the second capacitor digital-to-analog converter output voltage; and
an SAR logic configured to control the first capacitor multiplexer, the second capacitor multiplexer, the first resistor multiplexer, and the second resistor multiplexer according to an output of the comparator.

8. The successive approximation analog-to-digital converter of claim 7,
wherein the first LSB capacitor comprises a bottom plate, and
wherein in the non-binary LSB conversion process, the first resistor multiplexer is configured to change the plurality of non-binary weighted divided voltages applied to the bottom plate of the first LSB capacitor to determine an n^{th} bit depending on a value determined for an (n−1)^{th} bit.

9. The successive approximation analog-to-digital converter of claim 8, wherein based on the first capacitor digital-to-analog converter performing the non-binary LSB conversion process to generate the first capacitor digital-to-analog converter output voltage, the second resistor multiplexer is configured to change the plurality of non-binary weighted divided voltages provided to the second capacitor digital-to-analog converter so as to provide the second capacitor digital-to-analog converter output voltage corresponding to a first additional divided voltage which is higher than the upper reference voltage of the resistor digital-to-analog converter and corresponding to a second additional divided voltage which is lower than the lower reference voltage.

10. The successive approximation analog-to-digital converter of claim 9, wherein based on the first additional divided voltage that is higher than the upper reference voltage by N_{RO} LSB being required at the bottom plate of the first LSB capacitor, a non-binary weighted divided voltage that is smaller by N_{RO} LSB than the non-binary weighted divided voltage applied to the bottom plate of the second LSB capacitor is applied, and based on the second additional divided voltage that being lower than the lower reference voltage by N_{RO} LSB is required at the bottom plate of the first LSB capacitor, a non-binary weighted divided voltage that is larger by N_{RO} LSB than the non-binary weighted divided voltage applied to the bottom plate of the second redundancy capacitor is applied.

11. A successive approximation analog-to-digital converter, comprising:
a first capacitor digital-to-analog converter configured to perform a non-binary conversion process including a redundancy bit, using a first redundancy capacitor and a first non-binary weighted capacitor array, for an analog input voltage, thereby sequentially generating a first capacitor digital-to-analog converter output voltage;
a second capacitor digital-to-analog converter configured to sequentially generate a second capacitor digital-to-analog converter output voltage, using a second redundancy capacitor, and a second non-binary weighted capacitor array; and
a comparator, configured to compare the first capacitor digital-to-analog converter output voltage and the second capacitor digital-to-analog converter output voltage,
wherein based on a number of digital codes being increased by a number of redundancy LSBs added by the first redundancy capacitor, the non-binary conversion process is performed by shifting a group of digital codes, including those added by the redundancy LSBs, within a range of the added redundancy LSBs,
wherein based on the non-binary conversion process being completed, the shifted redundancy LSBs are subtracted from the digital code, and the redundancy bit is removed.
